(19) United States
(12) Patent Application Publication
(10) Pub. No.: US 2006/0258192 A1
(43) Pub. Date: Nov. 16, 2006

(54) Bottom PCB surface mount electrical connector

(75) Inventors: Chong Yi, Mechanicsburg, PA (US); Eric Daniel Juntwait, Hummelstown, PA (US)

Correspondence Address: WEI TE CHUNG;FOXCONN INTERNATIONAL, INC., 1650 MEMOREX DRIVE, SANTA CLARA, CA, 95050, US

(73) Assignee: HON HAI PRECISION IND. CO., LTD.

(21) Appl. No.: 11/128,051

(22) Filed: May 11, 2005

(51) Int. Cl. H05K 1/00

(52) U.S. Cl. 439/83

(57) ABSTRACT

An electrical connector (100) to be mounted onto a substrate (3) having a first surface (30) and a second surface (32) includes an insulative housing (1) and a number of conductive contacts (2) assembled to the insulative housing. The insulative housing defines a mounting surface (102) to face the first surface (30) of the substrate (3) and a number of passages extending from the mounting surface (102) into the housing (1). The conductive contact includes a tail portion (22) substantially flushed to the mounting surface of the housing and a contacting portion (23) extending away from the mounting surface of the insulative housing for mating with an electrical component (4) mounted on the second surface of the substrate.

### BACKGROUND OF THE INVENTION

1. Field of the Invention

The present invention generally relates to an electrical connector, and more particularly to an electrical connector used for automobile.

2. Description of Related Art

To electrically connecting an outer component with a printed circuit board (PCB), traditional means is selectively soldering leads of the component to respective pads formed on the PCB. However, it is desirable to integrate all electrical components to the PCB at one time. With the development of electronic industry, high efficiency with low cost is current trend. However, the traditional selective solder of the component to the PCB alone is time consuming and costly without doubt which is out of current trend. In addition, the electrical connection between the component and the PCB through selective solder by hand may not be reliable.

Hence, a bottom PCB surface mount electrical connector is provided to address the problems mentioned above and meet the current trend.

### BRIEF SUMMARY OF THE INVENTION

Accordingly, an object of the present invention is to provide a bottom PCB surface mount electrical connector with simple structure for aid of time saving and low cost.

In order to achieve the above-mentioned object, an electrical connector in accordance with the present invention for being mounted onto a substrate having a first surface and a second surface comprises an insulative housing and at least one conductive contact assembled to the insulative housing. The insulative housing defines a mounting surface for facing the first surface of the substrate and at least one passage extending from the mounting surface into the housing. The at least one conductive contact comprises a tail portion substantially flushed to the mounting surface of the housing and a contacting portion extending away from the mounting surface of the insulative housing for mating with an electrical component mounted on the second surface of the substrate.

Other objects, advantages and novel features of the invention will become more apparent from the following detailed description of the present embodiment when taken in conjunction with the accompanying drawings.

### BRIEF DESCRIPTION OF THE DRAWINGS

FIG. 1 is a perspective view of an insulative housing of an electrical connector in accordance with the present invention;

FIG. 2 is a view similar to FIG. 1, but viewed from a different angle;

FIG. 3 is a perspective view of a conductive contact of the electrical connector of the present invention;

FIG. 4 is a perspective, assembled view of the electrical connector of the present invention;

FIG. 5 is a view similar to FIG. 4, but viewed from a different angle;

FIG. 6 is a top plan view of a printed circuit board to which the electrical connector of the present invention is assembled;

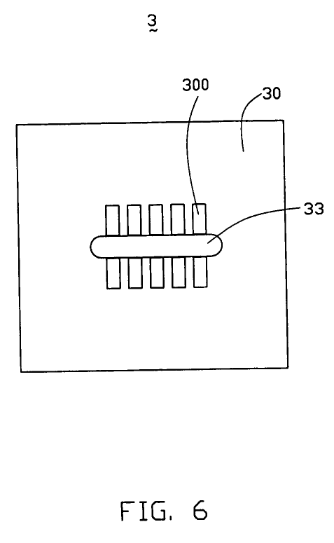

FIG. 7 is an assembled view of the electrical connector of the present invention with the printed circuit board;

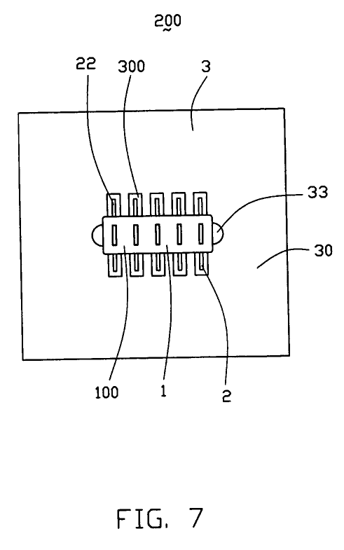

FIG. 8 is an assembled view of the electrical connector of the present invention with the printed circuit board and a complementary component; and

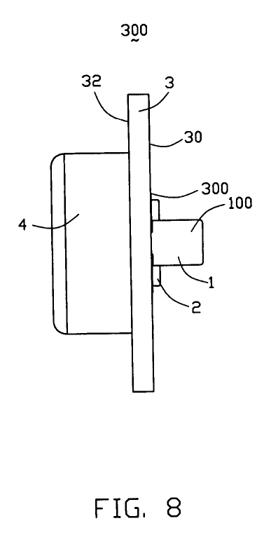

FIG. 9 is a cross-section view of FIG. 8.

### DETAILED DESCRIPTION OF THE INVENTION

Reference will now be made to the drawing figures to describe the present invention in detail.

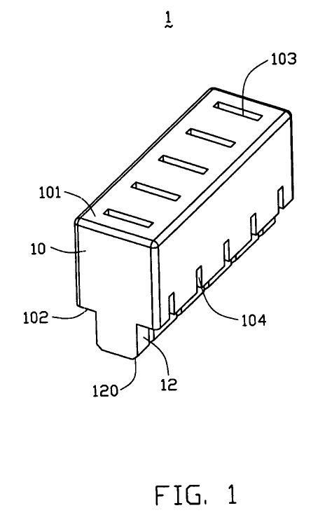

Referring to FIGS. 1-5, an electrical connector 100 in accordance with the present invention comprises an insulative housing 1 and a plurality of conductive contacts 2 assembled to the insulative housing 1. The electrical connector 100 is assembled to a substrate 3 to electrically connect with a complementary component 4 which is attached to the substrate 3.

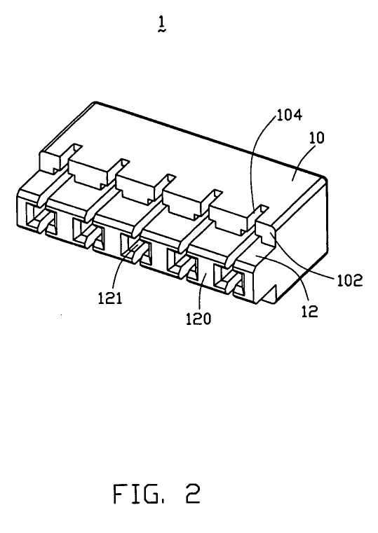

Please refer to FIGS. 1-2, the insulative housing 1 comprises a rectangular base portion 10 comprising a top surface 101 and an opposite bottom mounting surface 102, and a mating tongue portion 12 extending downwardly from the mounting surface 102 of the base portion 10. The tongue portion 12 defines a mating interface 120. A plurality of passages 103 extend downwardly from the top surface 101 of the insulative housing 1 and through opposite front and rear walls of the tongue portion 12. A plurality of rectangular-cross passageways 121 extend upwardly from the mating interface 120 of the tongue portion 12 to communicate with the passages 103. A plurality of slots 104 are respectively formed in lower portions of front and rear walls of the base portion 10 and aligned with respective passages 103 and passageways 121.

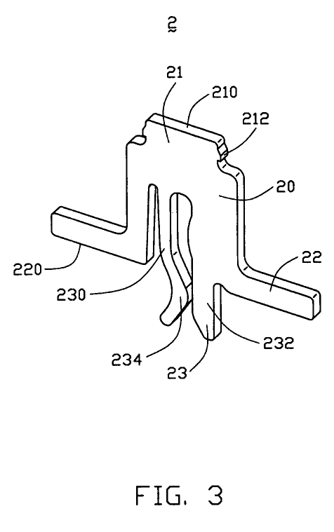

Referring to FIG. 3, each conductive contact 2 comprises a flat main portion 20, a retention portion 21 formed on a top of the main portion 20, a pair of tail portions 22 extending vertically from opposite lower edges of the main portion 20, and a dual-beam contacting portion 23 extending downwardly from the main portion 20 and perpendicular to the tail portion 22. The dual-beam contacting portion 23 comprises a first contact section 230 extending downwardly from a middle of the main portion 20 and a second contact section 232 extending downwardly from the lower edge of the main portion 20 and connecting with a respective tail portion 22. A contacting beam 234 is formed at lower portion of the first contact section 230 and curves toward the second contact section 232. The retention portion 21 forms a plurality of barbs 212 at opposite sides thereof.

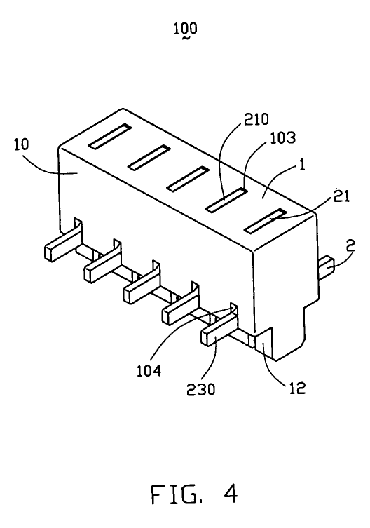

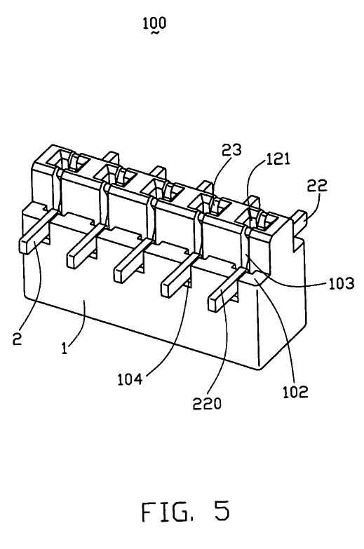

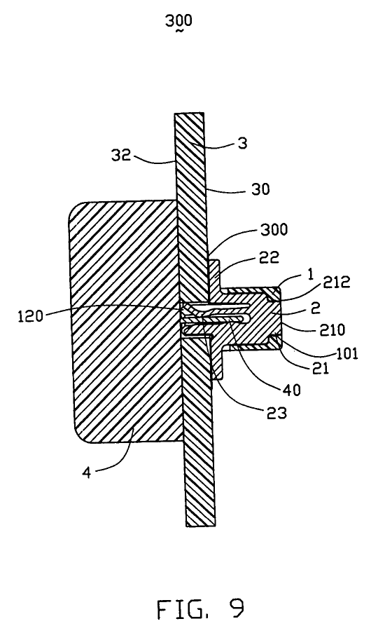

Referring to FIGS. 4 and 5 in conjunction with FIGS. 1-3 and 9, the conductive contacts 2 are assembled to the insulative housing 1 upwardly from the mating interface 120 of the insulative housing 1. The main portions 20 and the retention portions 21 are received in respective passages 103 of the housing 1 with top edge of each retention portion 21 coplanar with the top surface 101 of the housing 1. The barbs 212 of the retention portion 21 engage with inner surfaces of corresponding passage 103 for retaining the conductive contact 2 in the insulative housing 1. The tail portions 22 are respectively partially received in the slots 104 with free ends thereof exposed beyond the housing 1 and lower surface 220 of each tail portion 22 substantially coplanar with the mounting surface 102 of the housing 1. The first and second contact sections 230, 232 of the contacting portions 23 are respectively received in the passages 103 of the housing 1 with the contacting beams 234 of the first contact sections 230 exposed into the passageways 121 of the tongue portion 12.

The substrate 3 is a printed circuit board in the preferred embodiment and comprises a first surface 30 and an opposite second surface 32. A channel 33 extends from the first surface 30 to the second surface 32 of the substrate 3. A plurality of conductive pads 300 are respectively formed on the first surface 30 of the substrate 3 and located at opposite sides of the channel 33. The top surface 101 of the electrical connector 100 of the present invention is vacuum picked and placed on the first surface 30 of the substrate 3 to form an electrical assembly 200. The tongue portion 12 of the insulative housing 1 of the electrical connector 100 is inserted into the channel 33 with the mounting surface 102 of the base portion 10 of the insulative housing 1 abutting against the first surface 30 of the substrate 3. The tail portions 22 of the conductive contacts 2 are soldered to respective conductive pads 300 of the substrate 3. The mating interface 120 of the tongue portion 10 of the insulative housing 1 is proximate to the second surface 32 of the substrate 3.

The complementary component 4 is attached to the second surface 32 of the substrate 3 with leads 40 thereof respectively electrically connecting with the conductive contacts 2 of the electrical connector 100 and forms a subassembly 300. The leads 40 of the complementary component 4 are respectively inserted into the passageways 121 of the insulative housing 1 and each is sandwiched by the contacting beam 234 of the first contact section 230 and the second contact section 232 of the conductive contact 2.

It is to be understood, however, that even though numerous characteristics and advantages of the present invention have been set forth in the foregoing description, together with details of the structure and function of the invention, the disclosure is illustrative only, and changes may be made in detail, especially in matters of shape, size, and arrangement of parts within the principles of the invention to the full extent indicated by the broad general meaning of the terms in which the appended claims are expressed.

1. An electrical connector adapted to be mounted onto a substrate having a first surface and a second surface, comprising:
an insulative housing defining a mounting surface adapted to face the first surface of the substrate and a mating interface closer to the second surface of the substrate than the mounting surface adapted for mating with a compound mounted on the second surface of the substrate, the insulative housing defining at least one passage extending from the mounting surface into the housing;
at least one conductive contact assemble in said at least one passage of the insulative housing, the at least one conductive contact having a retention portion secured into the at least one passage, and a mounting portion and a contacting portion both extending away from the retention portion toward the mating interface of the insulative housing along the same direction.

2. The electrical connector as claimed in claim 1, wherein the insulative housing further comprises a top surface, and wherein the mounting surface is located between the top surface and the mating interface.

3. The electrical connector as claimed in claim 2, wherein the at least one passage extends from the mounting surface to the top surface of the insulative housing, and wherein the at least one contact comprises a top edge substantially flushed to the top surface of the insulative housing.

4. (canceled)

5. The electrical connector as claimed in claim 1, wherein the mounting portion of the at least one contact is substantially parallel to the mounting surface of the insulative housing, and wherein the contacting portion of the at least one contact is substantially perpendicular to the mounting portion.

6. The electrical connector as claimed in claim 1, wherein the contacting portion of the at least one contact includes a dual-beam configuration.

7. (canceled)

8. The electrical connector as claimed in claim 1, wherein the insulative housing further comprises a mating tongue portion substantially supporting the contacting portion of the at least one contact.

9. The electrical connector of claim 8, wherein the tongue portion of the insulative housing defines at least one passageway extending from the mating interface thereof to communicate with the at least one passage, and wherein the contacting portion of the at least one contact is received in the at least one passageway.

10. The electrical connector of claim 1, wherein the insulative housing comprises a base portion, and wherein the tongue portion extends downwardly from the mounting surface of the base portion.

11. The electrical connector as claimed in claim 10, wherein the base portion defines at least one slot extending away from the mounting surface thereof to align with the at least one passageway of the tongue portion, and wherein the mounting portion is partially received in the at least one slot.

12-14. (canceled)

15. An electrical connector assembly comprising:
a printed circuit board defining opposite bottom and top surfaces with a through opening extending therethrough;
an electrical connector comprising:
an insulative housing defining a main body with a mating tongue portion extending therefrom; and
a plurality of contacts received in the housing, each of said contacts including a mating portion disposed in the mating tongue portion, and a mounting portion extending away from said mating portion; wherein
the housing is essentially vertically assembled to the printed circuit board under a condition that the main body is essentially located on the bottom surface while the mating tongue portion extends into said opening toward the upper surface.

16. The assembly as claimed in claim 15, wherein the mounting portion is soldered upon the bottom surface.

17. The assembly as claimed in claim 15, wherein the contact defines a main portion essentially located around a bottom portion of the main body of the housing, from which said mating portion and said mounting portion extend, respectively.

18. The assembly as claimed in claim 15, wherein the mounting portion is essentially located adjacent to the mating tongue portion while relative far away from a bottom end of the main body.

19. The assembly as claimed in claim 15, wherein the mounting portion includes a pair of horizontal legs respectively outwardly extending by two sides of the main body.

20. An electrical connector assembly comprising:
a printed circuit board defining opposite bottom and top surfaces with a through opening extending therethrough;
an electrical connector comprising:
an insulative housing defining a main body; and
a plurality of contacts received in the housing, each of said contacts including a mating portion and a mounting portion extending away from said mating portion; wherein
the housing is assembled to the printed circuit board under a condition that the main body is essentially located on the bottom surface, and the mounting portion is thus mounted upon the bottom surface while the mating portion extends into said opening toward the upper surface.

21. The electrical connector assembly as claimed in claim 20, wherein said housing hirer includes a mating tongue portion extending from the main body, said mating tongue portion defining a plurality of longitudinal passageways to receive the mating portion of the corresponding contacts.

22. The electrical connector assembly as claimed in claim 21, wherein said passageways extend transversely through the corresponding wall of the mating tongue portion.
